(19) United States
(12) Patent Application Publication
(10) Pub. No.: US 2011/0037511 A1
(43) Pub. Date: Feb. 17, 2011

(54) MULTIPLE SIGNAL SWITCHING CIRCUIT, CURRENT SWITCHING CELL CIRCUIT, LATCH CIRCUIT, CURRENT STEERING TYPE DAC, SEMICONDUCTOR INTEGRATED CIRCUIT, VIDEO DEVICE, AND COMMUNICATION DEVICE

(75) Inventors: Michiko TOKUMARU, Osaka (JP); Heiji IKOMA, Nara (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/912,502

(22) Filed: Oct. 26, 2010

Related U.S. Application Data
(63) Continuation-in-part of application No. PCT/JP2009/001578, filed on Apr. 6, 2009.

(30) Foreign Application Priority Data
Apr. 30, 2008 (JP) 2008-118635

(51) Int. Cl. H03K 17/687

(52) U.S. Cl. 327/427

(57) ABSTRACT

In a multiple signal switching circuit using four input signals IN1-IN4, a four-input latch circuit 3b is located. Four NAND circuits 6″ are used as the four-input latch circuit 3b, when one of the four signals IN1-IN4 is “L” and the other three are “H.” In each of the NAND circuits 6″, an output is coupled to one of the four input signals IN1-IN4, the three signals other than the coupled signal are coupled to inputs. Therefore, even in a multiple signal switching circuit having three or more input signals, timing errors among multiple signals to be output can be effectively reduced.

### CROSS-REFERENCE TO RELATED APPLICATION

This is a continuation of PCT International Application PCT/JP2009/001578 filed on Apr. 6, 2009, which claims priority to Japanese Patent Application No. 2008-118635 filed on Apr. 30, 2008. The disclosures of these applications including the specifications, the drawings, and the claims are hereby incorporated by reference in their entirety.

### BACKGROUND

The present disclosure relates to multiple signal switching circuits reducing timing errors caused by device mismatches and the like, and D/A converters using the switching circuits having excellent distortion characteristics even in high-speed operation.

At present, switching circuits are used for various purposes in semiconductor integrated circuits. Current summing D/A converters (hereinafter referred to as DACs) are provided as an example of using the switching circuits.

FIG. 7 illustrates a configuration of a conventional current steering DAC. In the figure, reference character 1 denotes a switching circuit, 10 denotes a current switching cell, I denotes a current source, O denotes a non-inverted output terminal, and NO denotes an inverted output terminal. A predetermined number of the current switching cells 10 are coupled in parallel where the number is determined by a bit number. Each of the current switching cells 10 includes the current source I coupled to a supply voltage, and the switching circuit 1 coupled between the current source I and the non-inverted output terminal O, and between the current source I and the inverted output terminal NO. In response to a digital input value, the switching circuit 1 switches and selects whether a current output from the current source I is supplied to the non-inverted output terminal O or to the inverted output terminal NO. Such a configuration is shown in U.S. Pat. No. 7,034,733.

By controlling the switching circuit 1 in response to the digital input value, a differential analog output value corresponding to the digital input value can be obtained. The non-inverted output terminal O and the inverted output terminal NO are often coupled to resistors to convert output currents to voltages.

FIG. 8A illustrates an example configuration of the current switching cell 10. FIG. 8B illustrates an internal configuration of a current source I of the current switching cell 10. In FIGS. 8A and 8B, S1-S2 denote switches, D1 denotes a first control signal, D2 denotes a second control signal, vbias 1 denotes a first bias voltage, vbias 2 denotes a second bias voltage, P1 denotes a current source transistor, and P2 denotes a cascode transistor. The current source I includes the current source transistor P1 and the cascode transistor P2 which are coupled in series. The first and second bias voltages vbias 1 and vbias 2 are supplied to gate terminals of the transistors.

In the switching circuit 1, the switch 51 is coupled between the current source I and the non-inverted output terminal O, and the switch S2 is coupled between the current source I and the inverted output terminal NO. The switch 51 is driven by the first control signal D1, and the switch S2 is driven by the second control signal D2. This is the configuration of the current switching cell.

In the switching circuit 1, the timing of switching the control signals is important. If the change timing of the control signals deviates from desired timing, the timing mismatch causes a glitch or distortion. Thus, a switch control circuit for controlling the switching circuit 1 is provided not to cause any glitch or distortion. FIGS. 9A and 9B illustrate a configuration of a conventional switch control circuit for controlling the switching circuit 1.

In FIGS. 9A and 9B, IN1 denotes a first input signal, IN2 denotes a second input signal, D1 denotes a first control signal, D2 denotes a second control signal, CLK denotes a clock, 2 denotes a switch control circuit, 4 denotes a switch, 5 denotes an inverter (or a buffer), and 11a and 11b denote two-input latch circuits. The first input signal IN1 and the second input signal IN2 are differential signals.

In the switch control circuit 2 of FIG. 9A, as shown in U.S. Pat. No. 5,689,257, input signals IN1 and IN2 are input to two switches 4 which are opened and closed at the same time by the clock CLK. An output from the switch 4 is sequentially transmitted to the two-input latch circuit 11a, two inverters 5, and the two-input latch circuit 11b.

The clock CLK controls the switches 4 to match timing of two input signals IN1 and IN2 to input the input signals to a following circuit. Only while the clock is “H,” the switches 4 input the input signals IN1 and IN2 to the two-input latch circuit 11a. While the clock is “L,” an input of the two-input latch circuit 11a is open. Thus, the first two-input latch circuit 11a holds a signal even when the input is open. The held signal is buffered by the inverter 5, and an ultimate signal is latched by the two-input latch circuit 11b not to cause any timing error and is output to the switching circuit 1.

In the switch control circuit 2 of FIG. 9B, respective Nch transistors N1 are coupled to two input terminals of the two-input latch circuit 11a. Switches 4 being Nch transistors are coupled to these Nch transistors N1 in series. When the switches 4 are off, an input data path is invalid, and the two-input latch circuit 11a holds output data regardless of input data. When the switches are on, the input data path is valid and an inverted signal of an input is output.

Furthermore, the two-input latch circuit 11a shown in FIG. 9A includes two inverters. In each of the inverters, one of two differential signals IN1 and IN2 is coupled to an input, and the other signal is coupled to an output. The two inverters have inputs and outputs cross-coupled to each other to form a latch circuit. As another configuration of the latch circuit, as shown in FIG. 10, two two-input NAND circuits are used, and one of differential input signals and an output of the other NAND circuit are input to two inputs of each of the NAND circuits.

Next, operation of the latch circuit 11a will be described using the switch control circuit 2 of FIG. 9A as an example.

Assume that, when two signals IN1 and IN2 input to the two-input latch circuit 11a change, one of the signals changes from “H” to “L” and the other changes from “L” to “H,” since they are the differential signals. If the timing of a signal supposed to change from “H” to “L” is later than the timing of a signal changing from “L” to “H,” the input starts to change to “H” while the output is held at “H” in one of the inverters. Then, the output of the inverter, i.e., the other signal is changed to “L” by the inverter. Thus, even when little timing mismatch occurs between the input signals, the two differential input signals are changed at the same timing by the latch circuit 11a, thereby reducing timing errors. Since other circuits operate similarly, the description thereof is omitted.

As described above, with respect to the two input signals (a pair of differential signals), the latch circuit using the two inverters allows the two signals being the differential signals to change at the same timing, thereby excellently reducing timing errors.

Then, FIG. 11A illustrates an example configuration of a conventional switch control circuit having two pairs of control signals.

In the figure, D3 denotes a third control signal, D4 denotes a fourth control signal, NCLK denotes an inverted output clock, and 6″ denotes a NAND circuit. The switch control circuit 2 includes four NAND circuits 6″. In each of the four NAND circuits 6″, the first input signal IN1 and the clock CLK, the second input signal IN2 and the clock CLK, the first input signal IN1 and the inverted clock NCLK, and the second input signal IN2 and the inverted clock NCLK are input. Outputs of the NAND circuits 6″ are buffered by buffers 5 to be the first to fourth control signals D1-D4. This is the configuration of a conventional four-input switch control circuit 2.

In the four-input switch control circuit 2, while the clock CLK is “H,” the first and second control signals D1 and D2 output differential signals. While the clock CLK is “L,” the third and fourth control signals D3 and D4 output differential signals. Furthermore, while no differential signal is output, the control circuit 2 is reset. That is, values shown in FIG. 11B are provided.

As can be seen from the figure, in a multiple signal switching circuit to which three or more signals are input, there is a time period in which no differential signal is output, and a pair of signals do not always function as differential signals. Thus, a conventional inverter-type two-input latch circuit, in which inversion of one of the differential input signals is sufficient, cannot be used for reducing timing errors among three or more input signals. Therefore, timing errors cannot be effectively reduced in a multiple signal switching circuit having three or more signals.

Next, as an example of using four-input switch control circuit, FIG. 12A-12C illustrate example configurations of conventional current switching cell circuits used for current steering DACs and the like.

In a switching circuit 1 shown in FIG. 12A, switches S1 and S3 are coupled between the current source I and the non-inverted output terminal O, and switches S2 and S4 are coupled between the current source I and the inverted output terminal NO. The switch S1 is driven by a first control signal D1, the switch S2 is driven by a second control signal D2, the switch S3 is driven by a third control signal D3, and the switch S4 is driven by a fourth control signal D4.

As shown in FIG. 8A, the switching circuit 1 can be conventionally implemented with a pair of switches. However, the switching circuit 1 shown in FIG. 12A includes two pairs of switches, i.e., switches S1 and S2, and switches S3 and S4. These two pairs of switches S1-S4 alternately output differential signals, and are reset, i.e., both are turned off, while outputting no differential signal. Since the two pairs of switches are included, the same number of four switches changes the states between on and off in each clock cycle. Thus, noise occurring in a source voltage being a common node of the switches intensively appears near a sampling frequency. When the switching circuit is used for a DAC, noise components are concentrated at a high-frequency side, thereby providing the advantage of reducing noise in a signal band. This configuration is called “differential quad-switching,” and is shown, for example, in Sungkyung Park, A Digital-to-Analog Converter Based on Differential Quad Switching, IEEE journal OF SOLID-STATE CIRCUITS, VOL. 37, No. 10, OCTOBER 2002.

### SUMMARY

However, for example, when the switch to be turned on is switched from the switch 1 to the switch 3, a current of the current source I is switched from the state of flowing through the switch 1 to the non-inverted output terminal O to the state of flowing through the switch 3 to the non-inverted output terminal O. At this time, the timing at which the switch 1 is changed from on to off does not completely coincide with the timing at which the switch 3 is changed from off to on, and thus, the current output from the non-inverted output terminal O transiently fluctuates. However, when the switch to be turned on is switched from the switch S2 to the switch S4, the current seen from the non-inverted output terminal O is changed from zero to zero, i.e., no fluctuation occurs. As such, there is the problem that the frequency of a noise component seen from the non-inverted output terminal O and the inverted output terminal NO depends on data.

FIGS. 12B and 12C illustrate other examples of the current switching cell circuit 10. In the figures, D5 denotes a fifth control signal, D6 denotes a sixth control signal, S5 and S6 denote switches, OR denotes a reset output terminal, and Ia and Ib denote current sources.

The circuit in FIG. 12B includes two current sources Ia, and Ib. A switch S1 is coupled between the current source Ia and a non-inverted output terminal O. A switch S2 is coupled between the current source Ia and an inverted output terminal NO. A switch S3 is coupled between the current source Ib and the non-inverted output terminal O. A switch S4 is coupled between the current source Ib and the inverted output terminal NO. A switch S5 is coupled between the current source Ia and a reset output terminal OR. A switch S6 is coupled between the current source Ib and the reset output terminal OR.

The switches S1 and S2 and the switches S3 and S4 alternately output differential signals. While no differential signal is output, a current of the current source I is output to the reset output terminal OR. With this configuration, as in the differential quad-switching, the same number of switches change the states between on and off in each clock cycle.

In the circuit shown in FIG. 12C, only a half of the circuit in FIG. 12B is used. While the switches S1 and S2 do not output any signal, and a current is output to the reset output terminal OR; the output of the DAC is also in a reset state.

Operation shown in FIGS. 12B and 12C are both, as described in U.S. Pat. No. 6,061,010, called “return-to-zero (RTZ) switching.” Similar to the differential quad-switching, the same number of switches change the states between on and off in each cycle. Therefore, the source voltage being a common node of the switches does not generate noise depending on data, but noise seen from the output depends on the data.

As described above, in a conventional switching circuit having a pair of differential signals, a latch circuit including two inverters is provided between an input signal and an output signal to effectively reduce timing errors between the differential signals. However, in a multiple signal switching circuit having three or more signals, since there is a period in which no differential signal is output, such a latch circuit including two inverters cannot be used, there by causing timing errors.

Furthermore, in the conventional current switching cell circuits shown in FIGS. 12A-12C, source voltages being common nodes do not generate noise depending on data, but noise components seen from outputs depend on the data.

It is a first objective of the present disclosure to effectively reduce timing errors among signals in a multiple signal switching circuit having three or more signals.

It is a second objective of the present disclosure to reduce data dependency of noise seen from an output of a source voltage being a common node of switches in a current switching cell circuit, and to allow the noise to have a constant frequency component regardless of the change of data.

In order to achieve the first objective, a multiple signal switching circuit of the present disclosure has three or more control signals, and reduces timing errors among the control signals by latching the three or more signals at the same time.

Furthermore, in order to achieve the second objective, in a current switching cell circuit of the present disclosure, capacitors are coupled between a plurality of input signal terminals and a non-inverted output terminal, and between the plurality of input signal terminals and an inverted output terminal. When no or less noise due to a change in a current path occurs, the current switching cell circuit generates noise by capacitive coupling. A pair of switches for reset are provided other than a pair of switches for signal output. When the switches for signal output do not change, the switches for reset are changed so that the fluctuation cycle of the common source voltage is constant to reduce data dependency of noise seen from an output of the common source voltage.

Specifically, the multiple signal switching circuit of the present disclosure includes a number N (where N is three or more) of switching elements. A number N of control signals for switching between conduction and non-conduction states are input to the number N of switching elements. A number M (where 3≦M≦N) of the control signals control each other, timing to change.

As such, the number M of control signals control each other, the timing to change, thereby effectively reducing timing errors among the input signals.

The current switching cell circuit of the present disclosure includes a current source circuit, a differential switching circuit including L (where L is two or more) pairs of switching elements, a non-inverted output node, and an inverted output node. The current switching cell circuit selects whether a current output from the current source circuit is supplied to the non-inverted output node or to the inverted output node. A number L of capacitors are coupled between the non-inverted output node and a number L of control signals controlling switching elements coupled to the inverted output node. Another number L of capacitors are coupled between the inverted output node and a number L of control signals controlling the switching elements coupled to the non-inverted output node.

With this configuration, when each capacitance is set so that influences of noise due to a change in the current path are equal to influences of noise due to the capacitive coupling, noise has a constant frequency component not depending on data in both cases where the noise is seen from the output side and where the noise is seen from the source side being a common node.

The latch circuit of the present disclosure has a number M (where M is three or more) of signals. Each of the number M of signals feeds back the other (M−1) signals.

Due to this feature, change timing of the number M of signals occurs at the same time, thereby reducing timing errors among the signals.

The current switching cell circuit of the present disclosure includes a current source circuit, a switching circuit including K (where K is one or more) pairs of switching elements and one pair of reset switching elements for reset, a non-inverted output node, an inverted output node, and one pair of reset output nodes. Any one of the pairs of switching elements and any one of the reset switching elements are conductive at the same time so that a current output from the current source circuit is divided to flow to either one of the non-inverted output node and the inverted output node, and to one of the reset output nodes.

As such, the current from the current source circuit is divided to flow either one of the pair of switching elements for data output, and either one of the pair of reset switching elements. When data is changed, the pairs of switching elements for data output are switched, and the pairs of rest switching elements are not switched. On the other hand, when data is not changed, the pairs of switching elements for data output are not switched, and the pairs of rest switching elements are switched. This makes the fluctuation cycle of the common source voltage constant.

As described above, according to the present disclosure, in a switching circuit having three or more control signals, timing errors among the signals can be reduced; and in a current switching cell circuit, a fluctuation cycle of a common source voltage is constant, thereby reducing data dependency of noise seen from an output side of the common source voltage.

### BRIEF DESCRIPTION OF THE DRAWINGS

FIG. 1A illustrates a configuration of an entire multiple signal switching circuit in a first embodiment of the present disclosure.

FIG. 1B illustrates an internal configuration of a switch control circuit included in the multiple signal switching circuit.

FIG. 1C illustrates an internal configuration of a four-input latch circuit included in the switch control circuit.

FIG. 1D illustrates an internal configuration of another four-input latch circuit included in the switch control circuit.

FIG. 1E illustrates another example of the internal configuration of the switch control circuit.

FIG. 2A illustrates a variation of the switch control circuit.

FIG. 2B illustrates an internal configuration of a three-input latch circuit included in the switch control circuit.

FIG. 3 illustrates a configuration of a current switching cell circuit in a second embodiment of the present disclosure.

FIG. 4A illustrates an internal configuration of a four-input latch circuit in a third embodiment of the present disclosure.

FIG. 4B illustrates a specific example of the four-input latch circuit.

FIG. 5 illustrates a variation of the four-input latch circuit.

FIG. 6A illustrates a configuration of a current switching cell circuit in a fourth embodiment of the present disclosure.

FIG. 6B illustrates a variation of the current switching cell circuit.

FIG. 7 illustrates a configuration of a conventional current steering DAC.

FIG. 8A illustrates an example configuration of a conventional current switching cell circuit.

FIG. 8B illustrates an internal configuration of a current source included in the current switching cell circuit.

FIG. 9A illustrates an example configuration of a conventional switch control circuit.

FIG. 9B illustrates another example configuration of the switch control circuit.

FIG. 10 illustrates an example configuration of a conventional two-input latch circuit.

FIG. 11A illustrates a configuration of a conventional four-input switch control circuit.

FIG. 11B illustrates the states of output of four control signals from the four-input switch control circuit.

FIG. 12A illustrates a configuration of a conventional current switching cell.

FIG. 12B illustrates another configuration of the current switching cell.

FIG. 12C illustrates another configuration of the current switching cell.

FIG. 13 illustrates a configuration of a conventional current switching cell of a differential quad-switching type.

### DETAILED DESCRIPTION

Embodiments of the present disclosure will be described hereinafter with reference to the drawings.

### First Embodiment

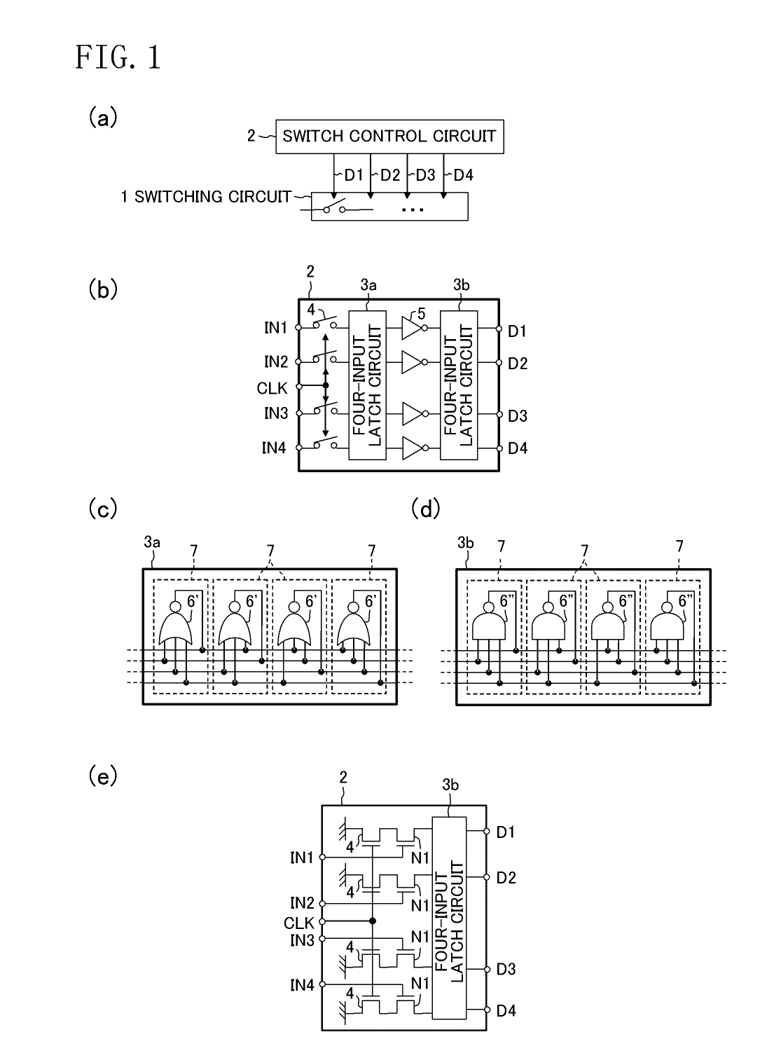

FIGS. 1A-1D illustrate a multiple signal switching circuit in a first embodiment of the present disclosure.

In the figures, reference numerals 3a and 3b denote four-input latch circuits, 6′ denotes a NOR circuit, 6″ denotes an NAND circuit, and 7 denotes a latch unit cell. As shown in the block diagram of FIG. 1A, four control signals D1-D4 output from the switch control circuit 2 drive switches in a switching circuit 1.

FIG. 1B illustrates an internal configuration of the switch control circuit 2. Four control signals IN1-IN4 are input to four switches 4 opened and closed at the same time by a clock CLK. Outputs of the four switches 4 are then, sequentially transmitted to the four-input latch circuit 3a, the inverters (or buffers) 5, and the four-input latch circuit 3b.

The four-input latch circuit 3a includes four latch unit cells 7, each of which has a NOR circuit 6′. In each NOR circuit 6′, its output is coupled to one of the four input control signals IN1-IN4, and the three signals other than the signal coupled to the output are coupled to inputs. Also, the four-input latch circuit 3b includes the four latch unit cells 7, each of which has a NAND circuit (logic circuit) 6″ as a switching element. In each NAND circuit 6″, its output is coupled to one of the four input signals IN1-IN4, and the three signals other than the signal coupled to the output are coupled to inputs. The NAND circuit 6″ is used to illustrate an example where one of the four signals IN1-IN4 is “L,” and the other three are “H.” Depending on a combination of signals, the type of the logic circuit is selected as appropriate. This is the configuration of the multiple signal switching circuit in the first embodiment.

Then, operation in the first embodiment will be described below.

First, the switch control circuit 2 in FIG. 1B will be described. The clock CLK controls the four switches 4 to match the change timing of the four input signals IN1-IN4 to input the signals IN1-IN4 to the four-input latch circuit 3a. Only while the clock is “H,” the input signals IN1-IN4 are input to the four-input latch circuit 3a. While the clock is “L,” the inputs of the four-input latch circuit 3a are open. Thus, the four-input latch circuit 3a holds the signals even when the inputs are open. The held signals are buffered by the inverters 5, and ultimate signals are latched by the four-input latch circuit 3b not to cause any timing error among the four signals IN1-IN4 and are output to the switching circuit 1.

Then, FIG. 1E illustrates another example configuration of the switch control circuit 2. In the switch control circuit 2 of the figure, input transistors N1, each of which is an Nch transistor, are coupled to four input terminals of the four-input latch circuit 3b. Switches 4 being Nch transistors are coupled to the input transistors N1 in series.

In the switch control circuit 2 of FIG. 1C, timing is designed in advance so that input signals IN1-IN4 change while the clock CLK is “L.” While the clock CLK is “L,” even when the input signals IN1-IN4 change, output signals do not change, since the four switches 4 are turned off. During this period, the output signals are held by the four-input latch circuit 3b. If the input signals IN1-IN4 change while the clock CLK is “L” and the switches 4 are turned on, input signals IN1-IN4 become valid at the timing when the clock CLK transitions from “L” to “H” to change the output signals. As such, the signals synchronized by the clock CLK are latched in the four-input latch circuit 3b, and output to the switching circuit 1.

In the four-input latch circuit 3b having the four input signals IN1-IN4, one of the four input signals is always “L,” and the other three input signals are “H.” Thus, even if the timing of an input signal to be “L” is later than desired timing, when the other three input signals change to “H,” the input signals coupled to outputs of the NAND circuit 6″ start to change to “L,” since all of the three inputs of the NAND circuits 6″ become “H.”

Therefore, timing mismatch among the four input signals IN1-IN4 can be reliably adjusted by using this four-input latch circuit 3b.

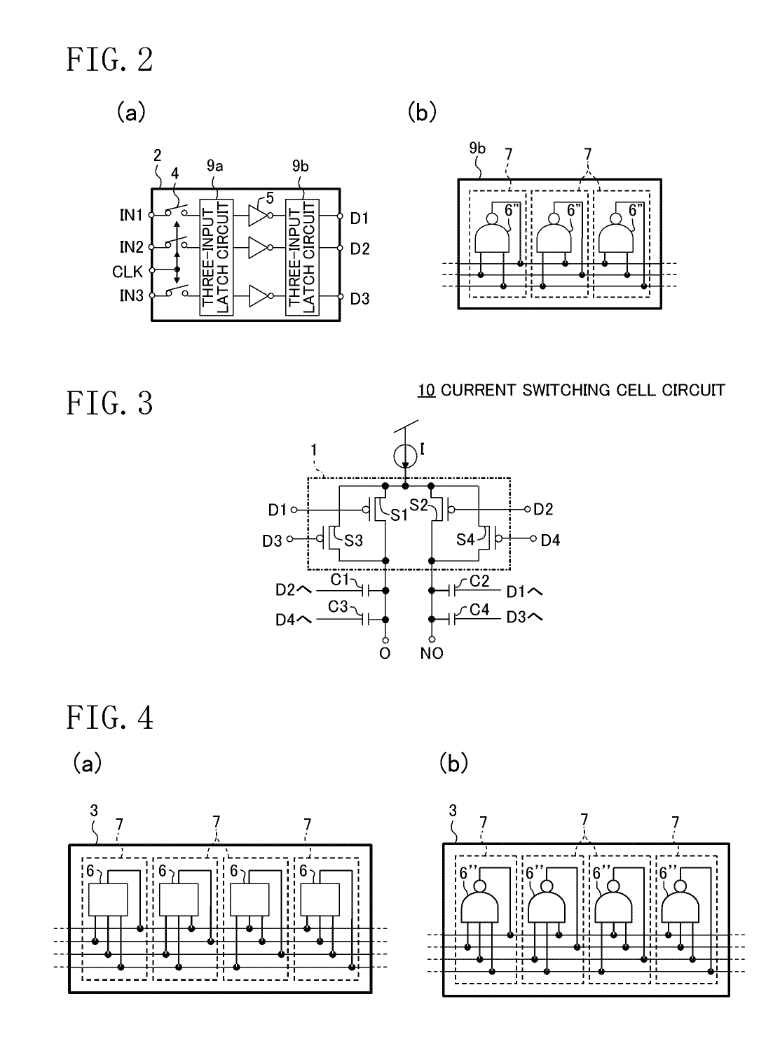

As such, in the switch control circuit 2 having four input signals IN1-IN4, timing errors among the input signals IN1-IN4 can be reduced by including the four-input latch circuit 3b for controlling the timing of the four input signals IN1-IN4 at the same time. Note that the four-input switch control circuit 2 is applicable not only to the case using four input signals, but to the case using three input signals or five or more input signals. FIG. 2 illustrates a specific example of a switch control circuit used for three input signals. Circuits may be used in combination. For example, two pairs of three-input switch control circuits may be combined.

Such circuits can be used for a current steering DAC and the like using differential quad-switching or RTZ switching.

By using the above-described multiple signal switching circuit with the switch control circuit 2, timing errors can be reduced in the multiple signal switching circuit having three or more input signals.

### Second Embodiment

FIG. 3 illustrates an example configuration of a current switching cell circuit in a second embodiment of the present disclosure.

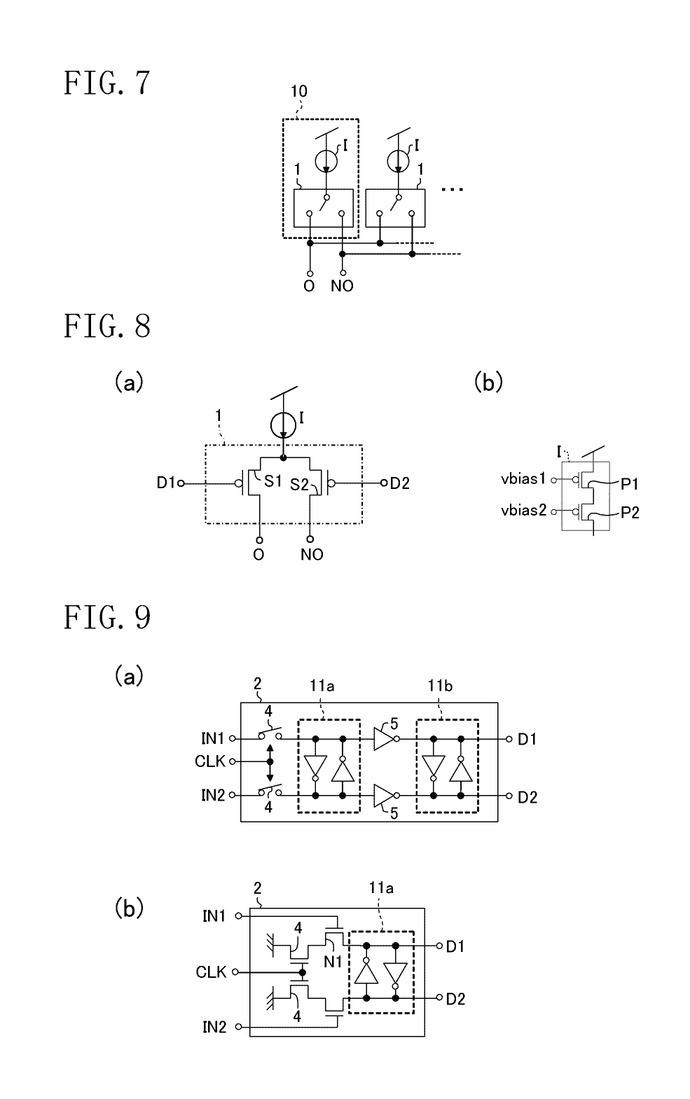

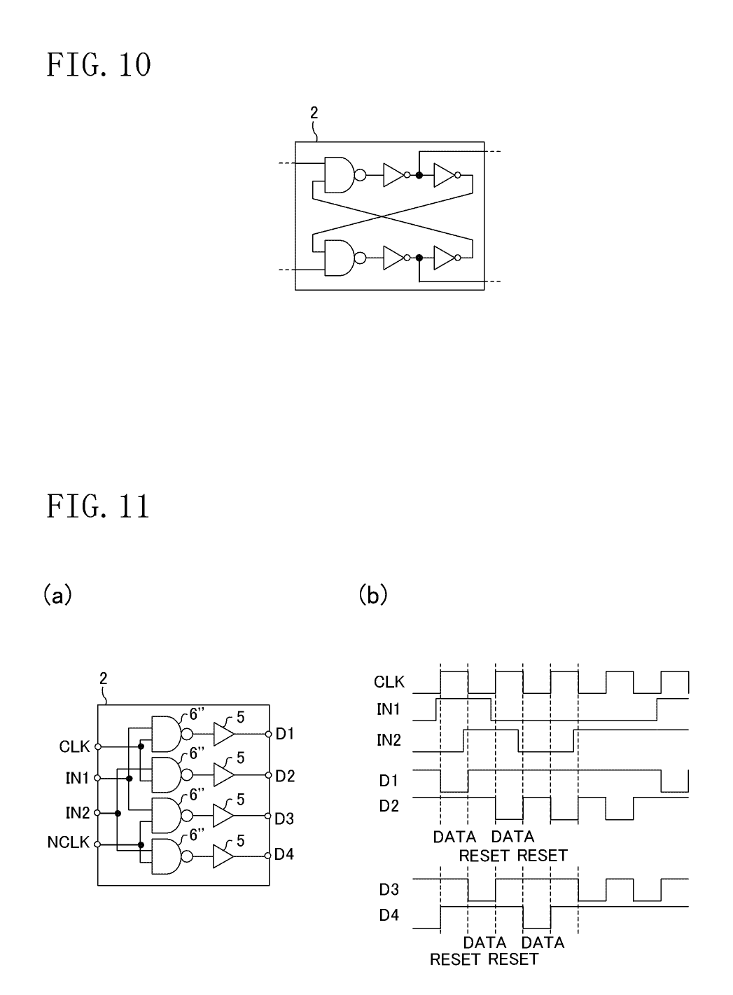

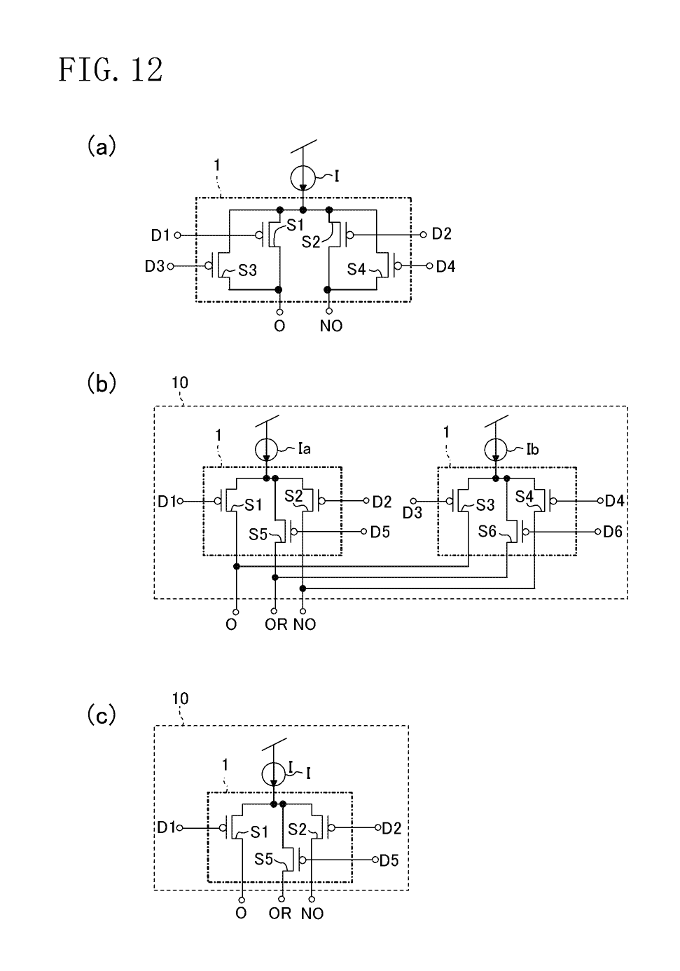

In FIG. 3, in a current switching cell circuit 10 used for, e.g., a current steering DAC, as described in the conventional example, a switching circuit 1 selects whether a current of a current source (a current source circuit) I from a power source is supplied to a non-inverted output terminal O or to an inverted output terminal NO. The switching circuit 1 includes the switch control circuit 2 shown in FIG. 1B, and the first to fourth control signals D1-D4 from the switch control circuit 2 are input to the switching circuit 1. The switching circuit 1 is a differential switching circuit including a pair of switches (pair switching elements) 51 and S2 operated by the first and second control signals D1 and D2, and another pair of switches (pair switching elements) S3 and S4 operated by the third and fourth control signals D3 and D4. Only one switching circuit 1 is shown in FIG. 3. However, in order to form a current steering DAC, the switching circuit 1 is used as a sub-switching circuit, and two or more sub-switching circuits 1 are coupled in parallel as shown in FIG. 7.

In the current switching cell circuit 10, capacitors C1 and C3 are coupled between the non-inverted output terminal O and the second control signal D2, and between the non-inverted output terminal O and the fourth control signal D4, respectively. Capacitors C2 and C4 are coupled between the inverted output terminal NO and the first control signal D1, and between the inverted output terminal NO and the third control signal D3, respectively. This is the configuration of the current switching cell circuit in this second embodiment.

Then, operation in the second embodiment will be described below. In the switching circuit 1, the terminal D1 is coupled to the non-inverted output terminal O with a gate-drain capacitor of the switch 1, and the terminal D3 is coupled to the non-inverted output terminal O with a gate-drain capacitor of the switch 3. For example, when the switch to be turned on is switched from the switch S1 to the switch S3, an end D1 of the gate-drain capacitor of the switch S1 and an end D3 of the gate-drain capacitor of the switch S3 change. Then, the non-inverted output terminal O at the other end follows the terminals and starts to change. Thus, when seen from the non-inverted output terminal O, noise corresponding to the fluctuations at the terminals D1 and D3 occurs. At this time, since the other ends D2 and D4 of the capacitors C1 and C3 coupled to the non-inverted output terminal O do not fluctuate, noise due to the capacitive coupling with the capacitors C1 and C3 is not generated. Furthermore, when the switch to be turned on is switched from the switch S2 to the switch S4, D1 and D3 coupled to the non-inverted output terminal O by gate-drain capacitors of the switches do not fluctuate. Thus, noise due to the gate-drain capacitors of the switches seen from the non-inverted output terminal O is not generated. However, both of the other ends D2 and D4 of the capacitors C1 and C3 coupled to the non-inverted output terminal O fluctuate to cause noise due to capacitive coupling through the capacitors C1 and C3 in the non-inverted output terminal O. Similar operation occurs when the switch to be turned on is changed from S1 to S4, S3 to S2, etc.

Therefore, when capacitances are set so that influences of noise due to the gate-drain capacitors of the switches are equal to influences of noise due to the capacitors of C1-C4, noise has a constant frequency component not depending on data in both cases where the noise is seen from the outputs and where the noise is seen from the source being the common node.

As such, in a multiple signal switching circuit including a plurality of pairs of switches, capacitors are included between a non-inverted output terminal and a plurality of signals at an inverted output, and between an inverted output terminal and a plurality of signals at a non-inverted output so that noise seen from the outputs has a constant frequency.

Note that MOS capacitors may be used for the capacitors C1-C4. While in this embodiment, description is provided with a differential quad-switching circuit, but the present disclosure is applicable to a return-to-zero switching circuit (RTZ) including a plurality of pairs of switches.

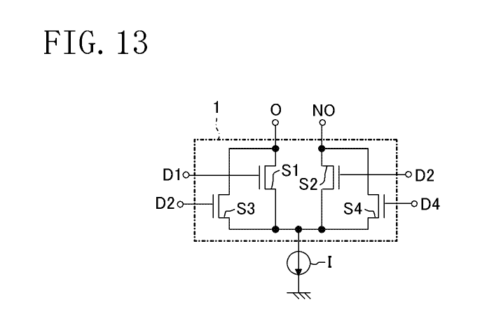

Also, the present disclosure is applicable to a current switching cell in which a current is supplied from ground and an Nch transistor is used to form a switching circuit. FIG. 13 illustrates an example current switching cell of a differential quad-switching type in this case.

With this configuration, by allowing noise seen from the output of a current switching cell circuit to have a constant frequency, noise components in the signal band can be reduced.

Note that this embodiment is described using as the current switching cell circuit 10, a circuit including a non-inverted output terminal O and an inverted output terminal NO. However, the circuit may include a reset output terminal as described below (see FIG. 6).

### Third Embodiment

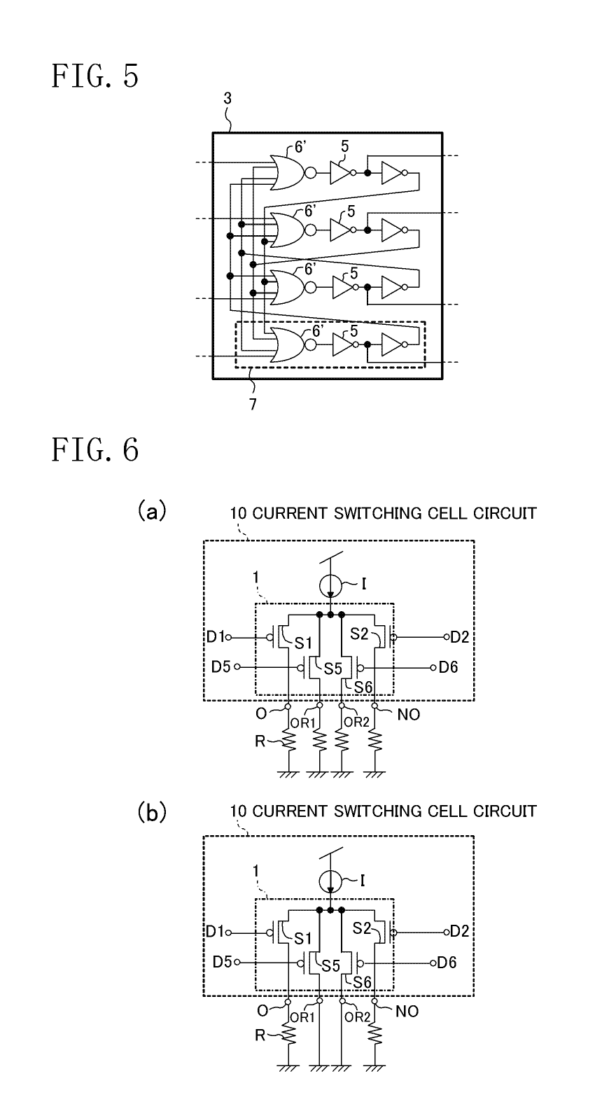

Next, a third embodiment of the present disclosure will be described. FIGS. 4 and 5 illustrate a four-input latch circuit in the third embodiment.

In a four-input latch circuit 3 shown in FIG. 4A, reference numeral 6 denotes a logic circuit, which is provided to correspond to each of four input signals. Each of the logic circuits 6 feeds back three of the four input signals to the other input signal. That is, one of the four input signals is coupled to an output of one of the logic circuits 6, and the other three input signals are coupled to inputs of the logic circuit 6. This configuration is referred to as a latch unit cell 7, and provides feedback to each of the input signals. Therefore, in a four-input latch circuit, four latch unit cells 7 are needed. At this time, an appropriate logic circuit is selected depending on the correlation among the four input signals. For example, in a circuit where one of four input signals is always “L,” and the other three signals are “H,” a NAND circuit 6″ may be used as the logic circuit 6 as shown in FIG. 4B.

Furthermore, FIG. 5 illustrates another example configuration of the four-input latch circuit 3. In the figure, four NOR circuits 6′ are provided for four input signals. In each of the NOR circuit 6′, one input signal and outputs of the other three NOR circuits 6′ are input to the NOR circuit 6′. This configuration is referred to as the latch unit cell 7, which is provided for each of the four input signals. This example configuration can be used for a circuit where only one of four input signals is always “L,” and the other three signals are “H.” As other circuits, the type of the logic circuit 6′ may be selected as appropriate depending on the correlation among the four input signals. This is the configuration of the four-input latch circuit in the third embodiment.

Next, operation in the third embodiment will be described below. First, operation of the four-input latch circuit in FIG. 4B will be described.

In a four-input latch circuit having four input signals, only one of which is always “L” and the other three are “H,” when one of the input signals is “L,” the other three signals are “H.” Assume that the timing of the input signal, which should be “L”, is later than desired timing. When the other three input signals change to “H,” the input signal coupled to the output of this NAND circuit 6″ starts to change to be “L,” since three of the inputs of the NAND circuit 6″ become “H.” When the signals have other values, similar changes occur. Therefore, the timing mismatch of the four input signals can be adjusted by using a four-input latch circuit. Since the operation in FIG. 5 is almost similar to that in FIG. 4B, the description thereof is omitted.

As such, in the four-input latch circuit having four input signals, the other input signals are fed back to each of the input signals, thereby matching the timing. Therefore, the latch circuits shown in FIGS. 4A, 4B, and 5 are used as the latch circuit 3b in the switch control circuit 1 shown in FIG. 1B.

Note that the four-input latch circuit is used as an example for illustrative purposes, the present disclosure is also applicable not only to circuits using four input signals, but three input signals, or five or more input signals; and can be used as the switch control circuit in the first embodiment.

### Fourth Embodiment

Then, a fourth embodiment of the present disclosure will be described. FIG. 6 illustrates a current switching cell circuit of the fourth embodiment. One of the features of this current switching cell circuit 10 is that a pair of reset output terminals OR1 and OR2, and that resistors R are coupled to a non-inverted output terminal O, an inverted output terminal NO, and the pair of reset output terminals (reset output nodes) OR1 and OR2.

Specifically, the current switching cell circuit 10 shown in FIG. 6A includes a switching circuit 1, which includes the switch control circuit 2 similar to that shown in FIG. 1B. First to fourth control signals D1, D2, D5, and D6 from the switch control circuit 2 are input to the switching circuit 1. The switching circuit 1 includes a pair of switches (pair switching elements) 51 and S2 operated by the first and second control signals D1 and D2, and another pair of switches (reset switching elements for reset) S5 and S6 operated by the fifth and sixth control signals D5 and D6. The switch 51 is coupled between a current source I and the non-inverted output terminal O. The switch S2 is coupled between the current source I and the inverted output terminal NO. The switch S5 is coupled between the current source I and the reset output terminal OR1. The switch S6 is coupled between the current source I and the reset output terminal OR2.

Note that only one switching circuit 1 is shown in FIG. 6. However, in order to form a current steering DAC, each switching circuit 1 is used as a sub-switching circuit, and two or more sub-switching circuits 1 are coupled in parallel as shown in FIG. 7. When a plurality of sub-switching circuits 1 are included, a predetermined number of one or more sub-switching circuit 1 is used as a unit to form a multiple signal switching circuit including the switch control circuit 2 shown in FIG. 1B.

Then, operation of the current switching cell circuit 10 in this embodiment will be described.

In the current switching cell circuit 10, as shown in the conventional example, when data is changed, two differential switches S1 and S2 are switched and a source voltage being a common node of the switches fluctuates. On the other hand, when data is not changed, the switches S1 and S2 do not change, and thus, the source voltage does not fluctuate. Thus, with only the differential switches, noise depending on data occurs in the source voltage. In order to reduce the noise, two switches S5 and S6 for reset are provided and operated in a differential manner. That is, when data is changed, the switches S5 and S6 for reset are not switched. When data is not changed, the switches S5 and S6 for reset are switched. Thus, a current output from the current source I flows after being divided into either one of the two differential switches S1 and S2 which is conductive, and either one of the two differential switches S5 and S6 for reset which is conductive. This makes the fluctuation cycle of the source voltage constant.

Furthermore, when currents output from the non-inverted output terminal O and the inverted output terminal NO are converted to voltages by a resistor R, since the voltages between the drains and sources of the switches S1, S2, S5, and S6 are different, the current output to the non-inverted output terminal O or the inverted output terminal NO, and the current output to the reset output terminal OR1 or OR2 may not be constant. In order to prevent this problem, resistors are coupled to the reset output terminals OR1 and OR2 so that the drain-source voltage of one of the switches S1 and S2 which is on is as equal as possible to the drain-source voltage of one of the switches S5 and S6 for reset which is on. Note that, instead of this configuration, constant voltages capable of reducing influences of noise may be applied to both of the reset output terminals OR1 and OR2. In FIG. 6B, ground potential may be applied to the terminals OR1 and OR2. A supply voltage, a half of the maximum output voltage, or the maximum output voltage may be applied to each of the terminals OR1 and OR2. Furthermore, constant voltages applied to the two reset output terminals OR1 and OR2 may have different potentials from each other.

As such, by including a plurality of switches OR1 and OR2 for reset, the frequency component of noise at the common node of the switches can be constant. Furthermore, by coupling a resistor R to a reset output terminal, or by applying an appropriate voltage to the reset output terminal, degradation of properties can be prevented even when the switches S5 and S6 for reset and the switches S1 and S2 for output signals are turned on at the same time.

Note that this embodiment is also applicable to a current switching cell in which a current is supplied from ground and an Nch transistor is used to form a current switching cell circuit.

With the above-described configuration, noise seen from the common node of the switches of the current switching cell circuit can have a constant frequency.

Clearly, the capacitors C1-C4 in FIG. 3 may be added to the configurations in FIG. 6A or 6B.

As described above, the present disclosure includes a multiple signal switching circuit which improves timing accuracy and reduces distortion, and is thus useful as a semiconductor integrated circuit, a video system, and a communication system including a current steering DAC, and the multiple signal switching circuit.

1-21. (canceled)

22. A multiple-signal switching circuit, comprising
a number N (where N is three or more) of switching elements, wherein
a number N of control signals for switching between conduction and non-conduction states are input to the number N of switching elements, and
a number M (where 3≦M≦N) of the control signals control each other, timing to change.

23. The multiple-signal switching circuit of claim 22, further comprising a latch circuit configured to latch the number M of control signals at a same time to control timing each other.

24. The multiple-signal switching circuit of claim 23, wherein the latch circuit is a logic circuit.

25. A current switching cell circuit comprising the multiple-signal switching circuit of claim 22, wherein
the current switching cell circuit configured to select a path through which a current output from a current source flows using a switching circuit being the multiple-signal switching circuit.

26. A current switching cell circuit including the multiple-signal switching circuit of claim 22, the current switching cell circuit comprising:
a current source circuit;
a differential switching circuit being the multiple-signal switching circuit, and including L (where L is two or more) pairs of switching elements;
a non-inverted output node; and
an inverted output node, wherein
the current switching cell circuit selects whether a current output from the current source circuit is supplied to the non-inverted output node or to the inverted output node.

27. The current switching cell circuit of claim 26, wherein
in the L pairs of switching elements, any one of the switching elements is conductive in every L cycles, and not conductive in the other cycle(s).

28. A current switching cell circuit including the multiple-signal switching circuit of claim 22, the current switching cell circuit comprising:
a current source circuit;
a switching circuit being the multiple-signal switching circuit, and including K (where K is one or more) pairs of switching elements and one pair of reset switching elements for reset;
a non-inverted output node;
an inverted output node; and
one pair of reset output nodes, wherein
the current switching cell circuit selects to which of the non-inverted output node, the inverted output node, and one of the reset output nodes, a current output from the current source circuit is supplied.

29. The current switching cell circuit of claim 28, wherein
any one of the K pairs of switching elements and one pair of the reset switching elements are alternately conductive.

30. A current switching cell circuit including the multiple-signal switching circuit of claim 22, the current switching cell circuit comprising:
a current source circuit;
at least one sub-switching circuit including K (where K is one or more) pairs of switching elements and one pair of reset switching elements for reset, where one or a number P (where 2≦P≦J) of the sub-switching circuits are multiple-signal switching circuits;
a non-inverted output node;
an inverted output node; and
one pair of reset output nodes, wherein
a number J (where J is two or more) of circuits, each of which selects to which of the non-inverted output node, the inverted output node, and one of the reset output nodes, a current output from the current source circuit is supplied, are coupled in parallel to form a single current switching cell circuit.

31. The current switching cell circuit of claim 30, wherein
any one of the K×J pairs of switching elements is conductive in every K×J cycles, and
where the current source circuit is not coupled to the non-inverted output node or the inverted output node, the one pair of reset switching elements is conductive.

32. A current steering DAC comprising the multiple-signal switching circuit of claim 25.

33. A latch circuit having a number M (where M is three or more) of signals, wherein
each of the number M of signals feeds back the other (M−1) signals.

34. The latch circuit of claim 33 having the number M (where M is three or more) of signals and a number M of logic circuits, wherein
each of the number M of signals is coupled to an output of the corresponding one of the logic circuits, and
in each of the number M of logic circuits, the (M−1) signals other than the signal coupled to an output terminal of the logic circuit are input to input terminals of the logic circuit.

35. The latch circuit of claim 33 having the number M (where M is three or more) of signals and number M of logic circuits, wherein
in each of the number M of logic circuits, outputs of the other (M−1) logic circuits and one signal are input.

36. The multiple-signal switching circuit of claim 23 comprising a latch circuit having a number M (where M is three or more) of signals, wherein
each of the number M of signals feeds back the other (M−1) signals.

37. A current switching cell circuit comprising the multiple-signal switching circuit of claim 36.

38. A current steering DAC comprising the multiple-signal switching circuit of claim 36.

39. A semiconductor integrated circuit comprising the multiple-signal switching circuit of claim 22.

40. A video system comprising the semiconductor integrated circuit of claim 39.

41. A communication system comprising the semiconductor integrated circuit of claim 39.

42. A semiconductor integrated circuit comprising the latch circuit of claim 33.

43. A video system comprising the semiconductor integrated circuit of claim 42.

44. A communication system comprising the semiconductor integrated circuit of claim 42.

45. A current switching cell circuit configured to select a path through which a current output from a current source flows using a switching circuit, wherein
the switching circuit is the multiple-signal switching circuit of claim 23.

46. A current switching cell circuit comprising:
a current source circuit;
a differential switching circuit including L (where L is two or more) pairs of switching elements;
a non-inverted output node; and
an inverted output node, wherein
the current switching cell circuit selects whether a current output from the current source circuit is supplied to the non-inverted output node or to the inverted output node, and
the differential switching circuit is the multiple-signal switching circuit of claim 23.

47. A current switching cell circuit comprising:
a current source circuit;
a switching circuit including K (where K is one or more) pairs of switching elements and one pair of reset switching elements for reset;
a non-inverted output node;
an inverted output node; and
one pair of reset output nodes, wherein
the current switching cell circuit selects to which of the non-inverted output node, the inverted output node, and one of the reset output nodes, a current output from the current source circuit is supplied, and
the switching circuit is the multiple-signal switching circuit of claim 23.

48. A current switching cell circuit comprising:
a current source circuit;
a sub-switching circuit including K (where K is one or more) pairs of switching elements and one pair of reset switching elements for reset;
a non-inverted output node;
an inverted output node; and
one pair of reset output nodes, wherein
a number J (where J is two or more) of circuits, each of which selects to which of the non-inverted output node, the inverted output node, and one of the reset output nodes, a current output from the current source circuit is supplied, are coupled in parallel to form a single current switching cell circuit, and
one or a number P (where 2≦P≦J) of the sub-switching circuits are multiple-signal switching circuits of claim 23.

49. A current switching cell circuit comprising:
a current source circuit;
a switching circuit including K (where K is one or more) pairs of switching elements and at least one reset switching element for reset;
a non-inverted output node;
an inverted output node; and
at least one reset output node, wherein in the current switching cell circuit configured to select to which of the non-inverted output node, the inverted output node, and the reset output node, a current output from the current source circuit is supplied; the reset output node is coupled to a resistor.

50. The current switching cell circuit of claim 49, wherein
the at least one reset switching element includes a plurality of reset switching elements,
the at least one reset output node includes a plurality of reset output nodes, and
the reset output nodes are coupled to different resistors.

51. A current switching cell circuit comprising:
a current source circuit;
a switching circuit including K (where K is one or more) pairs of switching elements and a plurality of reset switching elements for reset;
a non-inverted output node;
an inverted output node; and
a plurality of reset output nodes, wherein in the current switching cell circuit configured to select to which of the non-inverted output node, the inverted output node, and one of the reset output nodes, a current output from the current source circuit is supplied; the reset output nodes are coupled to different potentials.

52. The current switching cell circuit of claim 49, wherein
any one of the K pairs of switching elements and the at least one reset switching element are alternately conductive.

53. The current switching cell circuit of claim 51, wherein
any one of the K pairs of switching elements and at least one of the reset switching elements are alternately conductive.

54. A current switching cell circuit comprising:
a current source circuit;
a switching circuit including K (where K is one or more) pairs of switching elements and one pair of reset switching elements for reset;
a non-inverted output node;
an inverted output node; and
one pair of reset output nodes, wherein
any one of the K pairs of switching elements and any one of the reset switching elements are conductive at a same time, and
a current output from the current source circuit is divided to flow to either one of the non-inverted output node and the inverted output node, and to one of the reset output nodes.

55. The current switching cell circuit of claim 49, wherein
the at least one reset switching element includes a plurality of reset switching elements,
any one of the K pairs of switching elements and any one of the reset switching elements are conductive at a same time, and
a current output from the current source circuit is divided to flow to either one of the non-inverted output node and the inverted output node, and to the at least one reset output node.

56. The current switching cell circuit of claim 51, wherein
any one of the K pairs of switching elements and any one of the reset switching elements are conductive at a same time, and
a current output from the current source circuit is divided to flow to either one of the non-inverted output node and the inverted output node, and to one of the reset output nodes.

57. The current switching cell circuit of claim 49, wherein
a number J (where J is two or more) of circuits, each of which selects to which of the non-inverted output node, the inverted output node, and the at least one reset output node, a current output from the current source circuit is supplied, are coupled in parallel to form a single current switching cell circuit.

58. The current switching cell circuit of claim 57, wherein
the at least one reset switching element includes a plurality of reset switching elements,
the at least one reset output node includes a plurality of reset output nodes, and
the reset output nodes are coupled to different resistors.

59. The current switching cell circuit of claim 51, wherein
a number J (where J is two or more) of circuits, each of which selects to which of the non-inverted output node, the inverted output node, and one of the reset output nodes, a current output from the current source circuit is supplied, are coupled in parallel to form a single current switching cell circuit.

60. The current switching cell circuit of claim 57, wherein
any one of the K×J pairs of switching elements is conductive in every K×J cycles, and
where the current source circuit is not coupled to the non-inverted output node or the inverted output node, the at least one reset switching element is conductive.

61. The current switching cell circuit of claim 59, wherein
any one of the K×J pairs of switching elements is conductive in every K×J cycles, and
where the current source circuit is not coupled to the non-inverted output node or the inverted output node, the reset switching elements are conductive.

62. A current switching cell circuit comprising:
a current source circuit;
a switching circuit including K (where K is one or more) pairs of switching elements and one pair of reset switching elements for reset;
a non-inverted output node;
an inverted output node; and
one pair of reset output nodes, wherein
any one of the K pairs of switching elements and any one of the reset switching elements are conductive at a same time, and
a number J (where J is two or more) of circuits, each of which divides a current output from the current source circuit to flow to either one of the non-inverted output node and the inverted output node, and to one of the reset output nodes, are coupled in parallel to form a single current switching cell circuit.

63. The current switching cell circuit of claim 57, wherein
the at least one reset switching element includes a plurality of reset switching elements,
any one of the K pairs of switching elements and any one of the reset switching elements are conductive at a same time, and
a current output from the current source circuit is divided to flow to either one of the non-inverted output node and the inverted output node, and to the at least one reset output node.

64. The current switching cell circuit of claim 59, wherein
any one of the K pairs of switching elements and any one of the reset switching elements are conductive at a same time, and
a current output from the current source circuit is divided to flow to either one of the non-inverted output node and the inverted output node, and to one of the reset output nodes.

65. The current switching cell circuit of claim 49, wherein
K is two or more,
number K of capacitors are coupled between the non-inverted output node, and number K of control signals controlling the switching elements coupled to the inverted output node, and
number K of capacitors are coupled between the inverted output node, and number K of control signals controlling the switching elements coupled to the non-inverted output node.

66. The current switching cell circuit of claim 51, wherein
K is two or more,
number K of capacitors are coupled between the non-inverted output node, and number K of control signals controlling the switching elements coupled to the inverted output node, and
number K of capacitors are coupled between the inverted output node, and number K of control signals controlling the switching elements coupled to the non-inverted output node.

67. The current switching cell circuit of claim 54, wherein
K is two or more,
number K of capacitors are coupled between the non-inverted output node, and number K of control signals controlling the switching elements coupled to the inverted output node, and
number K of capacitors are coupled between the inverted output node, and number K of control signals controlling the switching elements coupled to the non-inverted output node.

68. The current switching cell circuit of claim 62, wherein
K is two or more,
number K of capacitors are coupled between the non-inverted output node, and number K of control signals controlling the switching elements coupled to the inverted output node, and
number K of capacitors are coupled between the inverted output node, and number K of control signals controlling the switching elements coupled to the non-inverted output node.
